(19) United States
(12) Patent Application Publication
(10) Pub. No.: US 2024/0072218 A1
(43) Pub. Date: Feb. 29, 2024

(54) DISPLAY DEVICE AND METHOD FOR FABRICATING THE SAME

(71) Applicant: Samsung Display Co., LTD., Yongin-si (KR)

(72) Inventors: Tae Jin KONG, Yongin-si (KR); Myeong Hee KIM, Yongin-si (KR); Seul Ki KIM, Yongin-si (KR); Ji Eun PARK, Yongin-si (KR); Myeong Su SO, Yongin-si (KR)

(21) Appl. No.: 18/311,038

(22) Filed: May 2, 2023

(30) Foreign Application Priority Data
Aug. 24, 2022 (KR) 10-2022-0106222

(51) Int. Cl. H01L 33/50; H01L 25/075; H01L 33/10; H01L 33/38; H01L 33/44

(52) U.S. Cl. CPC H01L 33/505; H01L 25/0753; H01L 33/10; H01L 33/38; H01L 33/44; H01L 2933/0016; H01L 2933/0041

(57) ABSTRACT

The present disclosure provides a display device and a method for fabricating the same. According to one or more embodiments, a display device includes a substrate, pixel electrodes above the substrate, light-emitting elements above the pixel electrodes, extending in a thickness direction of the substrate, and having a polyhedral shape in the thickness direction, a width of a middle portion of the polyhedral shape being greater than a width of an upper portion of the polyhedral shape and greater than a width of a lower portion of the polyhedral shape, and a common electrode above the light-emitting elements.

### CROSS-REFERENCE TO RELATED APPLICATION

This application claims priority to, and the benefit of, Korean Patent Application No. 10-2022-0106222, filed on Aug. 24, 2022, in the Korean Intellectual Property Office, the disclosure of which is incorporated by reference in its entirety herein.

### BACKGROUND

### 1. Field

The present disclosure relates to a display device, and a method for fabricating the same.

### 2. Description of the Related Art

Display devices become more and more important as multimedia technology evolves. Accordingly, a variety of types of display devices, such as organic light-emitting display (OLED) devices and liquid-crystal display (LCD) devices, are currently used.

Display devices include a display panel, such as a light-emitting display panel and a liquid-crystal display panel, for displaying images. Among them, light-emitting display panel may include light-emitting diodes (LEDs). Light-emitting diodes may include an organic light-emitting diode using an organic material as a luminescent material, and an inorganic light-emitting diode using an inorganic material as a luminescent material.

To fabricate a display panel using inorganic light-emitting diodes as light-emitting diodes, micro LEDs are grown on a substrate, and the grown micro LEDs are transferred to a display panel.

### SUMMARY

Aspects of the present disclosure provide a display device that can acquire a process margin during a transfer process, and that can disperse etching damage to an active layer by way of performing primary patterning on a growth substrate and performing secondary patterning on a circuit substrate, and a method for fabricating the same.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a display device includes a substrate, pixel electrodes above the substrate, light-emitting elements above the pixel electrodes, extending in a thickness direction of the substrate, and having a polyhedral shape in the thickness direction, a width of a middle portion of the polyhedral shape being greater than a width of an upper portion of the polyhedral shape and greater than a width of a lower portion of the polyhedral shape, and a common electrode above the light-emitting elements.

The light-emitting elements may include a first semiconductor layer above the pixel electrodes, an active layer above the first semiconductor layer, and a second semiconductor layer above the active layer.

A width of the active layer may be greater than a width of the first semiconductor layer, and may be greater than a width of a top of the second semiconductor layer.

A cross section of the polyhedral shape may be a hexagon.

The light-emitting elements may include a first insulating layer on a first side surface, and a second insulating layer on the first insulating layer and on a second side surface adjacent to the first side surface.

The light-emitting elements may include respective insulating layers on a first side surface, and on a second side surface that is adjacent to the first side surface, and having different respective thicknesses.

The display device may further include a reflective layer on an outer side of the insulating layers.

The display device may further include a color filter above the common electrode overlapping the light-emitting elements.

The display device may further include a light-blocking member above the common electrode, and between the light-emitting elements in plan view.

The light-emitting elements may include a first light-emitting element for outputting a first light, a second light-emitting element for outputting a second light, and a third light-emitting element for outputting a third light.

The display device may further include a wavelength conversion layer between the light-emitting elements and the color filter for converting a wavelength of light, wherein the light-emitting elements are configured to output a first light.

The display device may further include a reflective layer on a side surface of the wavelength conversion layer.

According to one or more embodiments, a method of fabricating a display device includes patterning light-emitting elements on a growth substrate and in a stripe shape in plan view, forming a first insulating layer surrounding the light-emitting elements in plan view, transferring the light-emitting elements onto a circuit substrate, patterning the light-emitting elements to be in an island shape in plan view, forming a second insulating layer surrounding side surfaces of the light-emitting elements in plan view, and forming a common electrode above the light-emitting elements.

The transferring the light-emitting elements onto the circuit substrate may include transferring the light-emitting elements onto a temporary substrate, transferring the light-emitting elements onto a relay substrate, and transferring the light-emitting elements onto the circuit substrate.

The light-emitting elements grown on the growth substrate may include a first semiconductor layer, an active layer, and a second semiconductor layer sequentially stacked above the growth substrate, wherein the light-emitting elements transferred onto the circuit substrate include the first semiconductor layer, the active layer, and the second semiconductor layer sequentially stacked above the circuit substrate, and have a cross section of a polyhedral shape in a thickness direction, a width of a middle portion of the polyhedral shape being greater than a width of an upper portion of the polyhedral shape and greater a width of a lower portion of the polyhedral shape.

The transferring the light-emitting elements onto the circuit substrate may include bonding the light-emitting elements to the circuit substrate.

The method may further include forming a reflective layer surrounding the second insulating layer in plan view.

The method may further include growing a first light-emitting element for emitting a first light on a first growth substrate, a second light-emitting element for emitting a second light on a second growth substrate, and a third light-emitting element for emitting a third light on a third growth substrate.

The method may further include forming a space for a wavelength conversion layer and for a light-transmitting layer, and forming a partition wall, by applying an organic insulating material layer above the common electrode, and by etching the organic insulating material layer above the light-emitting elements, and forming the wavelength conversion layer and the light-transmitting layer above the space.

The light-emitting elements may be configured to emit a first light, wherein the light-transmitting layer is configured to transmit the first light, and wherein the wavelength conversion layer includes a first wavelength conversion layer that converts a first wavelength of the first light into a second wavelength of a second light, and a second wavelength conversion layer that converts the first wavelength of the first light into a third wavelength of a third light.

According to one or more embodiments of the present disclosure, it is possible to reduce etching damage to an active layer to improve light efficiency.

However, the aspects of the present disclosure are not limited to the aforementioned aspects, and various other aspects are included in the present specification.

### BRIEF DESCRIPTION OF THE DRAWINGS

The above and other aspects of the present disclosure will become more apparent by describing in detail embodiments thereof with reference to the attached drawings, in which:

FIG. 1 is a view showing a layout of a display device according to one or more embodiments of the present disclosure.

FIG. 2 is a view showing a layout of area A of FIG. 1.

FIG. 3 is a view showing a layout of pixels of a display panel according to one or more embodiments of the present disclosure.

FIG. 4 is a cross-sectional view showing an example of the display panel taken along the line A-A′ of FIG. 2.

FIG. 5 is a cross-sectional view showing an example of the display panel taken along the line B-B′ of FIG. 3.

FIG. 6 is a cross-sectional view showing an example of a display panel taken along the line C-C′ of FIG. 3.

FIG. 7 is an enlarged, cross-sectional view showing in detail an example of the light-emitting element of FIG. 5.

FIG. 8 is a cross-sectional view showing another example of the display panel taken along the line B-B′ of FIG. 3.

FIG. 9 is a cross-sectional view showing yet another example of the display panel taken along the line B-B′ of FIG. 3.

FIG. 10 is a cross-sectional view showing yet another example of the display panel taken along the line B-B′ of FIG. 3.

FIG. 11 is a flowchart for illustrating a method of fabricating a display device according to one or more embodiments of the present disclosure.

FIGS. 12 to 28 are cross-sectional views, and FIGS. 29 and 30 are perspective views, for illustrating the method of fabricating a display device according to one or more embodiments of the present disclosure.

FIG. 31 is a flowchart for illustrating a method of fabricating a display device according to one or more other embodiments of the present disclosure.

FIGS. 32 to 34 are cross-sectional views for illustrating the method of fabricating a display device according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

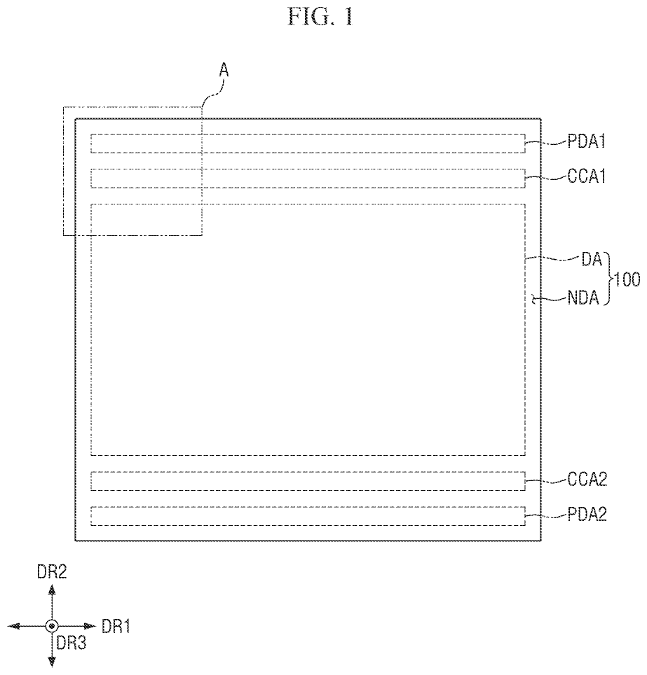

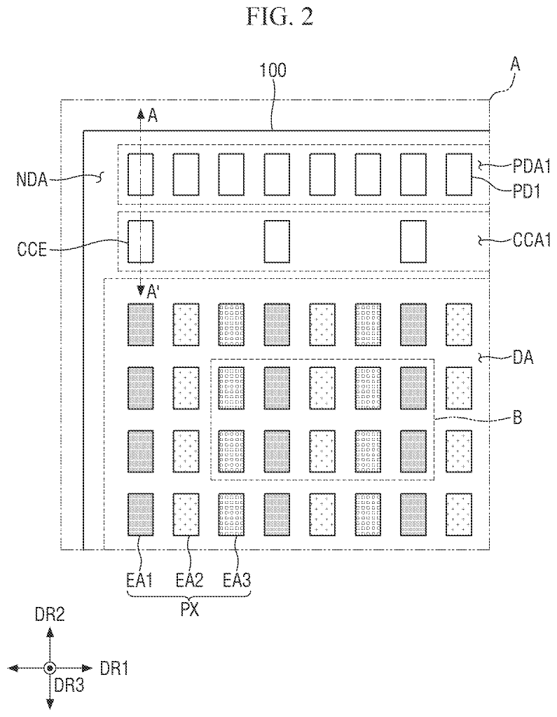

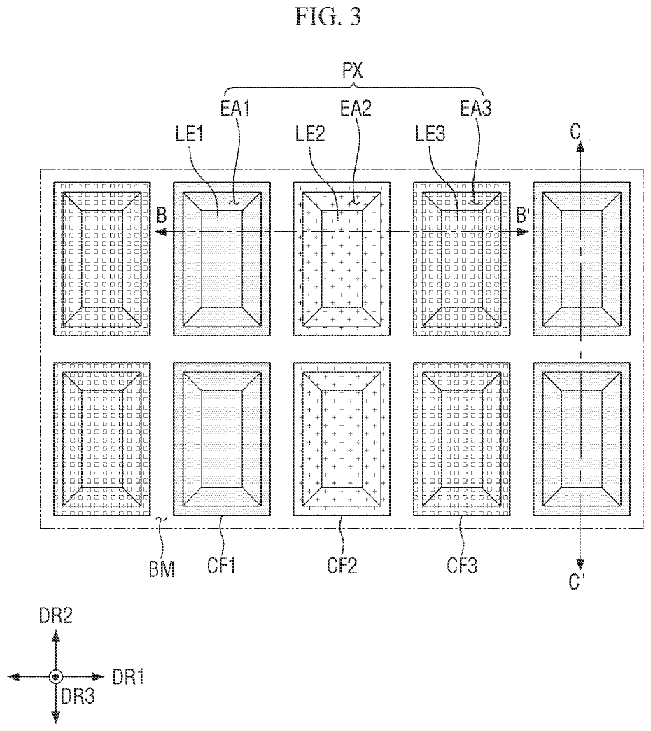

FIG. 1 is a view showing a layout of a display device according to one or more embodiments of the present disclosure. FIG. 2 is a view showing a layout of area A of FIG. 1. FIG. 3 is a view showing a layout of pixels of a display panel according to one or more embodiments of the present disclosure.

In the example shown in FIGS. 1 to 3, the display device is a micro or nano light-emitting diode display device including a micro or nano light-emitting diode as a light-emitting element. It should be understood, however, that the present disclosure is not limited thereto.

In addition, in the example shown in FIGS. 1 to 3, the display device is implemented as a light-emitting diode on silicon (LEDoS) micro-display (e.g., light-emitting diodes are located on a semiconductor circuit substrate 110 formed via a semiconductor process using a silicon wafer). It should be understood, however, that embodiments of the present disclosure are not limited thereto.

In FIGS. 1 to 3, a first direction DR1 indicates the horizontal direction of the display panel 100, a second direction DR2 indicates the vertical direction of the display panel 100, and the third direction DR3 refers to the thickness direction of the display panel 100 or to the thickness direction of the semiconductor circuit substrate 110. As used herein, the terms “left,” “right,” “upper” and “lower” sides indicate relative positions when the display panel 100 is viewed from the top (e.g., viewed in plan view). For example, the right side refers to one side in the first direction DR1, the left side refers to the other side in the first direction DR1, the upper side refers to one side in the second direction DR2, and the lower side refers to the other side in the second direction DR2. In addition, the upper portion refers to the side indicated by the arrow of the third direction DR3, while the lower portion refers to the opposite side in the third direction DR3.

Referring to FIGS. 1 to 3, a display device 10 according to one or more embodiments includes a display panel 100 including a display area DA and a non-display area NDA.

The display panel 100 may have a rectangular shape having longer sides in the first direction DR1 and shorter sides in the second direction DR2 when viewed from the top. It should be understood, however, that the shape of the display panels 100 when viewed from the top is not limited thereto. It may have a polygonal, circular, oval, or irregular shape other than the rectangular shape when viewed from the top.

In the display area DPA, images can be displayed. In the non-display area NDA, no image may be displayed. The shape of the display area DA may follow the shape of the display panel 100 when viewed from the top. In the example shown in FIG. 1, the display area DA has a rectangular shape when viewed from the top. The display area DA may be generally located at the central area of the display panel 100. The non-display area NDA may be located around the display area DA. The non-display area NDA may surround the display area DA.

The display area DA of the display panel 100 may include a plurality of pixels PX. Each of the pixels PX may be defined as a minimum light-emitting unit for displaying white light.

Each of the pixels PX may include a plurality of emission areas EA1, EA2 and EA3 from each of which light exits. Although each of the plurality of pixels PX may include three emission areas EA1, EA2 and EA3, the present disclosure is not limited thereto. For example, each of the plurality of pixels PX may include four emission areas.

Each of the first emission areas EA1 emits the first light. Each of the first emission areas EA1 may output the first light emitted from the light-emitting element LE as it is. The first light may be light in a blue wavelength range. The blue wavelength range may be about 370 nm to about 460 nm, but embodiments of the present disclosure are not limited thereto.

Each of the second emission areas EA2 emits a second light. Each of the second emission areas EA2 may convert a part of the first light emitted from the light-emitting element LE into the second light to output it. The second light may be light in a green wavelength range. The green wavelength range may be about 480 nm to about 560 nm, but embodiments of the present disclosure are not limited thereto.

Each of the third emission areas EA3 emits a third light. Each of the third emission areas EA3 may convert a part of the first light emitted from the light-emitting element LE into the third light to output it. The third light may be light in a red wavelength range. The red wavelength range may be about 600 nm to about 750 nm, but embodiments of the present disclosure are not limited thereto.

The first emission areas EA1, the second emission areas EA2, and the third emission areas EA3 may be arranged sequentially and repeatedly in the first direction DR1. For example, the first emission areas EA1, the second emission areas EA2, and the third emission areas EA3 may be arranged in the order of the first emission area EMA1, the second emission area EMA2, and the third emission area EMA3 in the first direction DR1.

The first emission areas EA1 may be arranged in the second direction DR2. The second emission areas EA2 may be arranged in the second direction DR2. The third emission areas EA3 may be arranged in the second direction DR2.

Each of the first emission areas EA1 may include a first light-emitting element LE1 and a first color filter CF1. The first light-emitting element LE1 and the first color filter CF1 may overlap each other in the third direction DR3. The first color filter CF1 may transmit the first light output from the first light-emitting element LE1. Therefore, each of the first emission areas EA1 may emit the first light.

Each of the second emission areas EA2 may include a second light-emitting element LE2 and a second color filter CF2. The second light-emitting element LE2 and the second color filter CF2 may overlap each other in the third direction DR3. The second color filter CF2 may transmit the second light output from the second light-emitting element LE2. Therefore, each of the second emission areas EA2 may emit the second light.

Each of the third emission areas EA3 may include a third light-emitting element LE3 and a third color filter CF3. The third light-emitting element LE3 and the third color filter CF3 may overlap each other in the third direction DR3. The third color filter CF3 may transmit the third light output from the third light-emitting element LE3. Therefore, each of the third emission areas EA3 may emit the third light.

The area of each of the first color filter CF1, the second color filter CF2, and the third color filter CF3 may be larger than that of the light-emitting element LE.

In the first emission area EA1, the first light-emitting element LE1 may be completely covered by the first color filter CF1. In the second emission area EA2, the second light-emitting element LE2 may be completely covered by the second color filter CF2. In the third emission area EA3, the third light-emitting element LE3 may be completely covered by the third color filter CF3.

In the example shown in the drawings, the shape of the first color filter CF1, the shape of the second color filter CF2, and the shape of the third color filter CF3, when viewed from the top, follow the shape of the first light-emitting element LE1, the shape of the second light-emitting element LE2, and the shape of the third light-emitting element LE3 when viewed from the top, respectively. For example, when the first light-emitting element LE1, the second light-emitting element LE2, and the third light-emitting element LE3 have a rectangular shape when viewed from the top, the first color filter CF1, the second color filter CF2, and the third color filter CF3 may each have a rectangular shape when viewed from the top. Alternatively, the first light-emitting element LE1, the second light-emitting element LE2, and the third light-emitting element LE3 may have a polygonal shape other than a rectangular shape, a circular shape, an elliptical shape, or an irregular shape. In this instance, the first color filter CF1, the second color filter CF2, and the third color filter CF3 may also have the polygonal shape other than the rectangular shape, the circular shape, the elliptical shape, or the irregular shape.

Alternatively, the shape of the first color filter CF1, the shape of the second color filter CF2, and the shape of the third color filter CF3 when viewed from the top may not follow the shape of the first light-emitting element LE1, the shape of the second light-emitting element LE2, and the shape of the third light-emitting element LE3 when viewed from the top, respectively. In this instance, the shapes of the first color filter CF1, the second color filter CF2, and the third color filter CF3, when viewed from the top, may be different from the shapes of the light-emitting elements LE. The non-display area NDA may include a first common connection area CCA1, a second common connection area CCA2, a first pad area PDA1, and a second pad area PDA2.

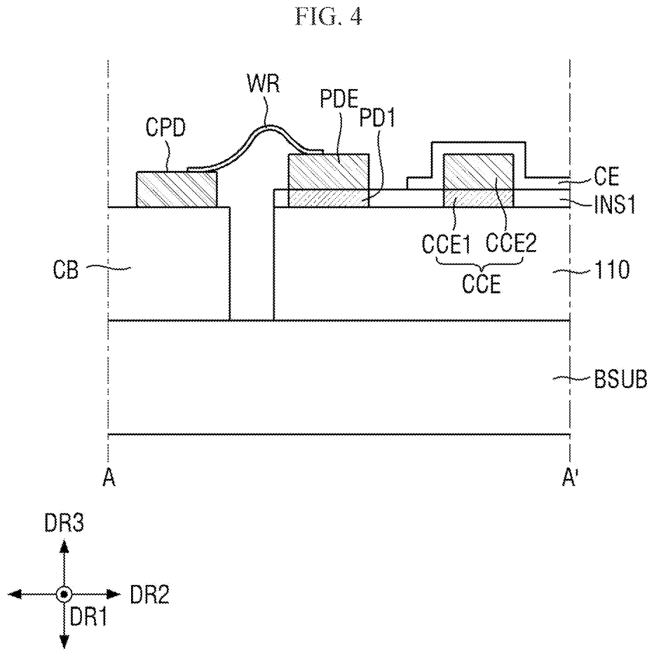

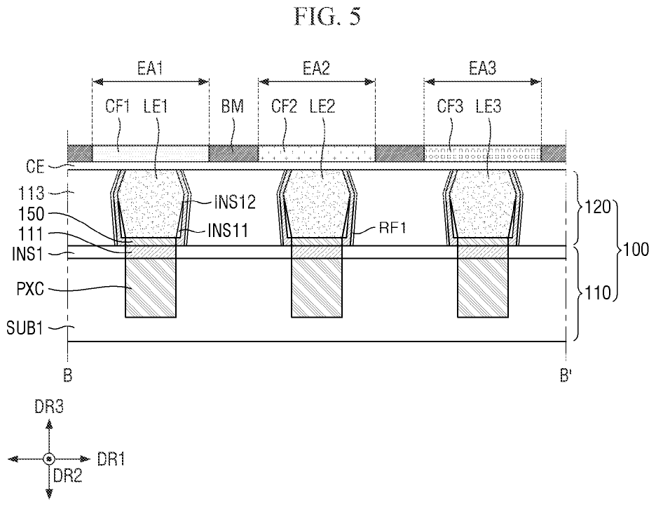

The first common connection area CCA1 may be located between the first pad area PDA1 and the display area DA. The second common connection area CCA2 may be located between the second pad area PDA2 and the display area DA. Each of the first common connection area CCA1 and the second common connection area CCA2 may include a plurality of common connection electrodes CCE connected to a common electrode CE (see FIGS. 4 and 5). Accordingly, the common voltage may be supplied to the common electrode CE (see FIGS. 4 and 5) through the plurality of common connection electrodes CCE. The plurality of common connection electrodes CCE of the first common connection area CCA1 may be electrically connected to one of first pads PD1 of the first pad area PDA1. The plurality of common connection electrodes CCE of the second common connection area CCA2 may be electrically connected to one of second pads PD2 of the second pad area PDA2. The first pad area PDA1 may be located on the upper side of the display panel 100. The first pad area PDA1 may include first pads PD1 connected to an external circuit board CB (see FIG. 4).

The second pad area PDA2 may be located on the lower side of the display panel 100. The second pad area PDA2 may include second pads PD2 connected to an external circuit board CB (see FIG. 4). The second pad area PDA2 may be omitted in other embodiments.

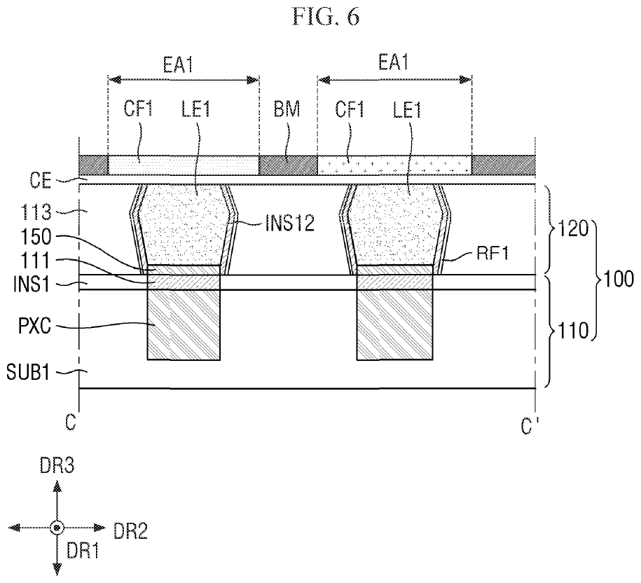

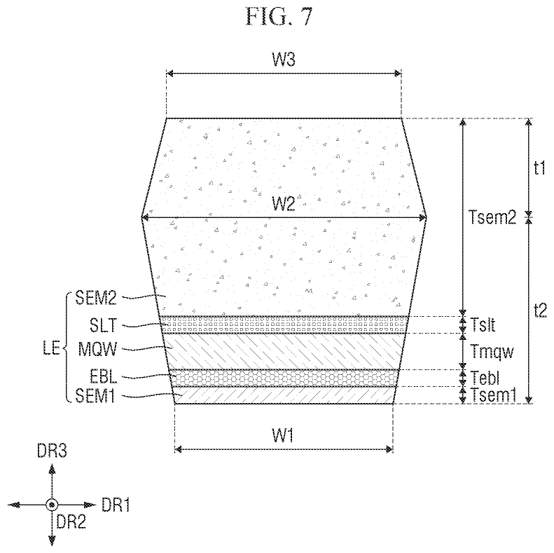

FIG. 4 is a cross-sectional view showing an example of the display panel taken along the line A-A′ of FIG. 2. FIG. 5 is a cross-sectional view showing an example of the display panel taken along the line B-B′ of FIG. 3. FIG. 6 is a cross-sectional view showing an example of a display panel taken along the line C-C′ of FIG. 3. FIG. 7 is an enlarged, cross-sectional view showing in detail an example of the light-emitting element of FIG. 5.

Referring to FIGS. 4 to 7, the display panel 100 may include the semiconductor circuit substrate 110, and a light-emitting element layer 120.

The semiconductor circuit substrate 110 may include a first substrate SUB1, a plurality of pixel circuits PXC, pixel electrodes 111, first pads PD1, a first common connection electrode CCE1 of a common connection electrode CCE, and a planarization layer INS1.

The first substrate SUB1 may be a silicon wafer substrate. The first substrate SUB1 may be made of monocrystalline silicon.

Each of the plurality of pixel circuits PXC may be located on the first substrate SUB1. Each of the plurality of pixel circuits PXC may include a complementary metal-oxide semiconductor (CMOS) circuit formed using a semiconductor process. Each of the plurality of pixel circuits PXC may include at least one transistor formed via a semiconductor process. In addition, each of the plurality of pixel circuits PXC may further include at least one capacitor formed via a semiconductor process.

The plurality of pixel circuits PXC may be located in the display area DA. The plurality of pixel circuits PXC may be connected to the pixel electrodes 111, respectively. In other words, the plurality of pixel circuits PXC and the plurality of pixel electrodes 111 may be connected in a one-to-one correspondence. Each of the plurality of pixel circuits PXC may apply a pixel voltage or an anode voltage to the pixel electrode 111.

The pixel electrodes 111 may be located on the pixel circuits PXC, respectively. Each of the pixel electrodes 111 may be an exposed electrode exposed from the respective pixel circuit PXC. In other words, each of the pixel electrodes 111 may protrude from the upper surface of the respective pixel circuit PXC. The pixel electrodes 111 may be formed integrally with the pixel circuits PXC, respectively. Each of the pixel electrodes 111 may receive a pixel voltage or an anode voltage from the respective pixel circuit PXC. The pixel electrodes 111 may include aluminum (Al).

Each of the first pad PD1 and the first common connection electrode CCE1 may be an exposed electrode exposed from the first substrate SUB1. The first pad PD1 and the first common connection electrode CCE1 may include the same material as the pixel electrodes 111. For example, the first pad PD1 and the first common connection electrode CCE1 may include aluminum (Al).

The second pads of the second pad area PDA2 may be substantially identical to the second pads PD2 described above with reference to FIG. 4. Therefore, redundant descriptions thereof will be omitted.

The planarization layer INS1 may be located on the first substrate SUB1 where the pixel electrodes 111, the first pads PD1, or the first common connection electrodes CCE1 are not located. The upper surface of the planarization layer INS1, the upper surface of each of the pixel electrodes 111, the upper surface of each of the first pads PD1, and the upper surface of each of the first common connection electrodes CCE1 may be evenly connected (e.g., may collectively be substantially flat). Alternatively, the planarization layer INS1 may cover the pixel electrodes 111, the first pads PD1, and the first common connection electrodes CCE1. In this instance, at least a part of each of the pixel electrodes 111, the first pads PD1, and the first common connection electrodes CCE1 may be exposed through contact holes penetrating through the planarization layer INS1 while not being covered by the planarization layer INS1. The planarization layer INS1 may be implemented as an inorganic film, such as a silicon oxide film (SiO₂), an aluminum oxide film (Al₂O₃) and a hafnium oxide film (HfOx).

The light-emitting element layer 120 may include a plurality of emission areas EA1, EA2, and EA3 to emit light. The light-emitting element layer 120 may include connection electrodes 150, a pad connection electrode PDE, a second common connection electrode CCE2 of a common connection electrode CCE, light-emitting elements LE, a first insulating layer INS11, a second insulating layer INS12, a common electrode CE, and a plurality of color filters CF1, CF2, and CF3. In addition, the light-emitting element layer 120 may further include a light-blocking member BM.

The connection electrodes 150 may be located on the pixel electrodes 111, respectively. That is to say, the connection electrodes 150 may be connected to the pixel electrodes 111, respectively. The connection electrodes 150 may work as bonding metals for bonding the pixel electrodes 111 to the light-emitting elements LE during a fabricating process. For example, the connection electrodes 150 may include at least one of gold (Au), copper (Cu), aluminum (Al), and/or tin (Sn). Alternatively, the connection electrodes 150 may include a first layer including one of gold (Au), copper (Cu), aluminum (Al) and tin (Sn), a second layer including another one of gold (Au), copper (Cu), aluminum (Al), and/or tin (Sn). In this instance, the second layer may be located on the first layer.

The pad connection electrode PDE may be located on the first pad PD1, and the second common connection electrode CCE2 may be located on the first common connection electrode CCE1. The pad connection electrode PDE may be in contact with the first pad PD1, and the second common connection electrode CCE2 may be in contact with the upper surface of the first common connection electrode CCE1. The pad connection electrode PDE and the second common connection electrode CCE2 may include the same material as the connection electrodes 150. For example, each of the pad connection electrode PDE and the second common connection electrode CCE2 may include at least one of gold (Au), copper (Cu), aluminum (Al), and/or tin (Sn). When each of the connection electrodes 150 includes a first layer and a second layer, each of the pad connection electrode PDE and the second common connection electrode CCE2 may include a first layer and a second layer.

The pad connection electrode PDE may be connected to a pad CPD of the circuit board CB through a conductive connection member, such as a wire WR. That is to say, the first pad PD1, the pad connection electrode PDE, the wire WR, and pad CPD of the circuit board CB may be electrically connected to one another.

The semiconductor circuit substrate 110 and the circuit board CB may be located on a base substrate BSUB. The semiconductor circuit substrate 110 and the circuit board CB may be attached to the upper surface of the base substrate BSUB using an adhesive member, such as a pressure sensitive adhesive.

The circuit board CB may be a flexible film, such as a flexible printed circuit board (FPCB), a printed circuit board (PCB), a flexible printed circuit (FPC), and a chip-on-film (COF).

The light-emitting elements LE may be located on the connection electrodes 150. The light-emitting element LE may be a vertical light-emitting diode or a flip chip light-emitting diode. According to one or more embodiments of the present disclosure, the light-emitting elements LE may be vertical light-emitting diodes extended in the third direction DR3. The vertical light-emitting diodes may have the length in the third direction DR3 that is greater than the length in the horizontal direction. The horizontal length refers to either the length in the first direction DR1 and/or the length in the second direction DR2. For example, the length of the light-emitting element LE in the third direction DR3 may be about 1 μm to about 5 μm.

The light-emitting elements LE may be micro light-emitting diodes or nano light-emitting diodes. The cross section of each of the light-emitting elements LE in the third direction DR3, which is the thickness direction, is formed in a polyhedron shape having an upper portion, a middle portion, and a lower portion. The width W3 of the upper portion and the width W1 of the lower portion are less than the width W2 of the middle portion. In other words, the longitudinal section of the light-emitting element LE has a polyhedral shape with a convex middle portion. For example, the light-emitting element LE may have a hexagonal shape.

The light-emitting element LE includes a first semiconductor layer SEM1, an electron-blocking layer EBL, an active layer MQW, a superlattice layer SLT, and a second semiconductor layer SEM2 in the third direction DR3. The first semiconductor layer SEM1, the electron-blocking layer EBL, the active layer MQW, the superlattice layer SLT, and the second semiconductor layer SEM2 may be stacked on one another in order in the third direction DR3.

The first semiconductor layer SEM1 may be located on the connection electrode 150. The first semiconductor layer SEM1 may be doped with a dopant of a first conductivity type, such as Mg, Zn, Ca, Se, and/or Ba. For example, the first semiconductor layer 31 may be p-GaN doped with p-type Mg. The thickness Tsem1 of the first semiconductor layer 31 may range from about 30 nm to about 200 nm.

The electron-blocking layer EBL may be located on the first semiconductor layer SEM1. The electron-blocking layer EBL may suppress or prevent too many electrons from flowing into the active layer MQW. For example, the electron-blocking layer EBL may be p-AlGaN doped with p-type Mg. The thickness Tebl of the electron-blocking layer EBL may be about 10 nm to about 50 nm. The electron-blocking layer EBL may be omitted in other embodiments.

The active layer MQW may be located on the electron-blocking layer EBL. The active layer MQW may emit light as electron-hole pairs that are combined therein in response to an electrical signal applied through the first semiconductor layer SEM1 and the second semiconductor layer SEM2. The active layer MQW may emit first light having a central wavelength range of about 450 nm to about 495 nm (e.g., light of the blue wavelength range). The width of the active layer MQW may be greater than the width W1 of the bottom surface of the light-emitting element LE/first semiconductor layer SEM1.

The active layer MQW may include a material having a single- or multiple-quantum well structure. When the active layer MQW includes a material having the multiple-quantum well structure, well layers and barrier layers may be alternately stacked on one another in the structure. The well layers may be made of InGaN, and the barrier layers may be made of GaN or AlGaN, but the present disclosure is not limited thereto. The thickness of the well layers may be about 1 nm to about 4 nm, and the thickness of the barrier layers may be about 3 nm to about 10 nm.

Alternatively, the active layer MQW may have a structure in which a semiconductor material having a large band gap energy and a semiconductor material having a small band gap energy are alternately stacked on one another, and may include other Group III to Group V semiconductor materials depending on the wavelength range of the emitted light. The light emitted by the active layer MQW is not limited to the first light (light in the blue wavelength range). In some implementations, the second light (e.g., light in the green wavelength range) or the third light (e.g., light in the red wavelength range) may be emitted by emitted by the active layer MQW.

The superlattice layer SLT may be located on the active layer MQW. The superlattice layer SLT may relieve stress between the second semiconductor layer SEM2 and the active layer MQW. For example, the superlattice layer SLT may be made of InGaN or GaN. The thickness Tslt of the superlattice layer SLT may range from about 50 nm to about 200 nm. The superlattice layer SLT may be omitted in other embodiments.

The second semiconductor layer SEM2 may be located on the superlattice layer SLT. The second semiconductor layer SEM2 may be doped with a dopant of a second conductivity type, such as Si, Ge, or Sn. For example, the second semiconductor layer SEM2 may be n-GaN doped with n-type Si. The thickness Tsem2 of the second semiconductor layer SEM2 may range from about 2 μm to about 1 μm.

The first insulating layer INS11 may be located on a first side surface of each of the plurality of light-emitting elements LE. The first insulating layer INS11 does not cover the entire side surface of the light-emitting element LE, but instead exposes a part thereof. The first insulating layer INS11 may not be located on a second side surface of each of the plurality of light-emitting elements LE that is adjacent to the first side surface. The first insulating layer INS11 may be implemented as, but is not limited to, an inorganic film, such as a silicon oxide film (SiO2), an aluminum oxide film (Al₂O₃), and/or a hafnium oxide film (HfOx).

The second insulating layer INS12 may be located on side surfaces of each of the light-emitting elements LE. The second insulating layer INS12 may be located on a first side surface of each of the light-emitting elements LE and on a second side surface adjacent to the first side surface. The second insulating layer INS12 may be located on the outer side of the first insulating layer INS11 to surround the side surface of the light-emitting element LE. The second insulating layer INS12 may be in direct contact with the light-emitting element LE where the first insulating layer INS11 is not located.

The second insulating layer INS12 may be implemented as, but is not limited to, an inorganic film, such as a silicon oxide film (SiO₂), an aluminum oxide film (Al₂O₃), and/or a hafnium oxide film (HfOx).

The first insulating layer INS11 and the second insulating layer INS12 may be collectively referred to as an insulating layer of the light-emitting element LE. The thickness of the insulating layer on the upper portion of the light-emitting element LE is different from the thickness of the insulating layer on the lower portion of the light-emitting element LE. The thickness of the insulating layer on the upper portion of the light-emitting element LE may be less than the thickness of the insulating layer on the lower portion of the light-emitting element LE.

The thickness of the insulating layer on the first side surface of the light-emitting element LE may be different from the thickness of the insulating layer on the second side surface adjacent to the first side surface.

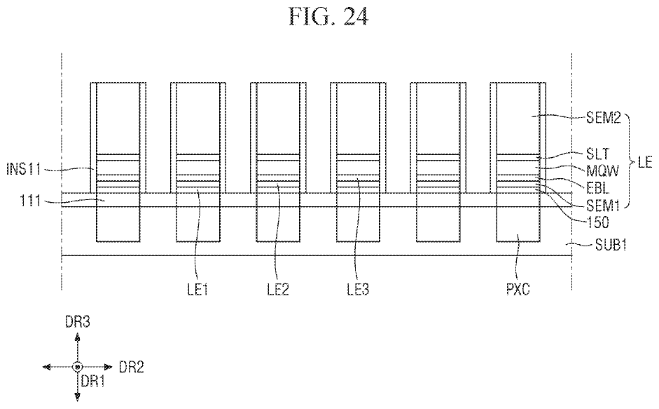

The thickness of such insulating layers will be described later with reference to FIG. 24.

A reflective layer RF1 may surround the second insulating layer INS12. The reflective layer RF1 serves to reflect some of the lights that are emitted from the light-emitting element LE and that travel in other directions than the vertical direction. The reflective layer RF1 may include a metal material having high reflectivity, such as aluminum (Al). The thickness of the reflective layer RF1 may be about 0.1 μm.

The common electrode CE may be located on the upper surface of each of the light-emitting elements LE, the upper surface of the planarization layer INS1, and the upper surface of the second insulating layer INS2. The common electrode CE may completely cover each of the light-emitting elements LE.

The common electrode CE may include a transparent conductive material. For example, the common electrode CE may include a transparent conductive oxide (TCO), such as indium tin oxide (ITO), and/or indium zinc oxide (IZO).

The plurality of color filters CF1, CF2, and CF3 may include first color filters CF1, second color filters CF2, and third color filters CF3.

Each of the first color filters CF1 may be located on the common electrode CE in the first emission area EA1. The first color filter CF1 overlaps the first light-emitting element LE1 in the third direction DR3. Each of the first color filters CF1 may transmit the first light and may absorb or block the second light and the third light. For example, each of the first color filters CF1 may transmit light in the blue wavelength range, and may absorb or block light in the green and red wavelength ranges. Therefore, each of the first color filters CF1 may transmit the first light output from the first light-emitting element LE1. That is to say, the first light output from the first light-emitting element LE1 in the first emission area EA1 may not be converted by any wavelength conversion layer, and may pass through the first color filter CF1. Therefore, each of the first emission areas EA1 may emit the first light.

Each of the second color filters CF2 may be located on the common electrode CE in the second emission area EA2. The second color filter CF2 overlaps the second light-emitting element LE2 in the third direction DR3. Each of the second color filters CF2 may transmit the second light, and may absorb or block the first light and the third light. For example, each of the second color filters CF2 may transmit light in the green wavelength range and may absorb or block light in the blue and red wavelength ranges. Therefore, each of the second color filters CF2 may transmit the second light output from the second light-emitting element LE2. That is to say, the second light output from the second light-emitting element LE2 in the second emission area EA2 may not be converted by a separate wavelength conversion layer, but instead may pass through the second color filter CF2. Therefore, each of the second emission areas EA2 may emit the second light.

Each of the third color filters CF3 may be located on the common electrode CE in the third emission area EA3. Each of the third color filters CF3 may transmit the third light, and may absorb or block the first light and the second light. For example, each of the third color filters CF3 may transmit light in the red wavelength range, and may absorb or block light in the blue and green wavelength ranges. Therefore, each of the third color filters CF3 may transmit the third light output from the third light-emitting element LE3. That is to say, the third light output from the third light-emitting element LE3 in the third emission area EA3 may not be converted by a separate wavelength conversion layer, but instead may pass through the third color filter CF3. Accordingly, each of the third emission areas EA3 may emit the third light.

A black matrix may be located between the plurality of color filters CF1, CF2, and CF3 as the light-blocking member BM. For example, the black matrix may be located between the first color filter CF1 and the second color filter CF2, between the second color filter CF2 and the third color filter CF3, and between the first color filter CF1 and the third color filters CF3. The black matrix may include an inorganic black pigment, such as carbon black or an organic black pigment.

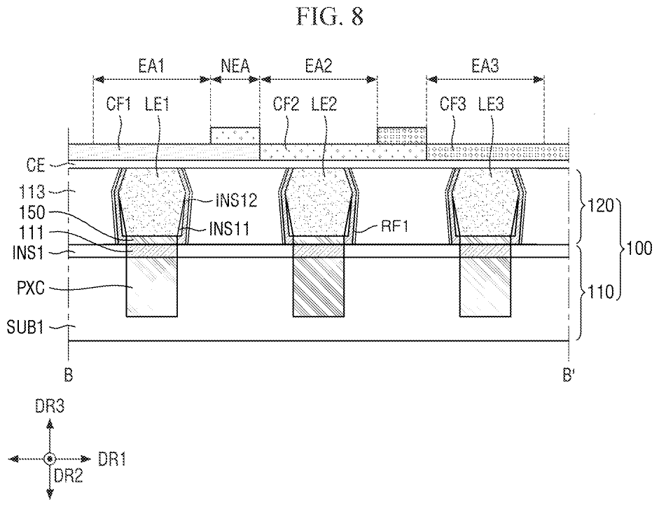

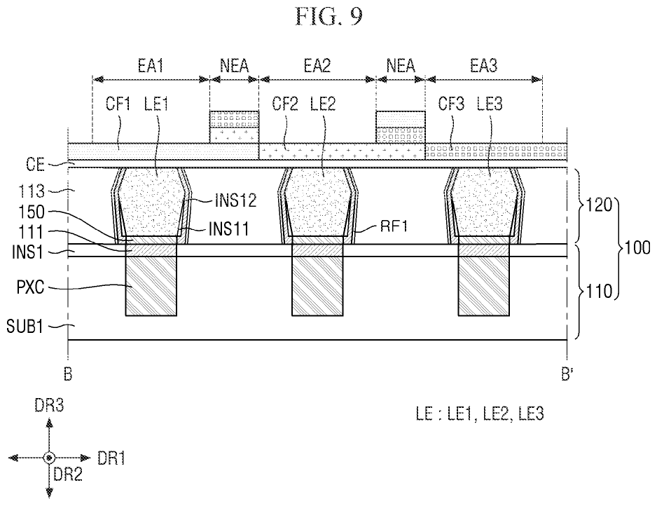

FIG. 8 is a cross-sectional view showing another example of the display panel taken along the line B-B′ of FIG. 3. FIG. 9 is a cross-sectional view showing yet another example of the display panel taken along the line B-B′ of FIG. 3.

As shown in FIGS. 8 and 9, to simplify the fabricating process, a plurality of color filters CF1, CF2, and CF3 overlapping each other may be used as the light-blocking member BM in FIG. 5, instead of the black matrix. For example, as shown in FIG. 8, the first color filter CF1 and the second color filter CF2 may be located in the non-emission area NEA between the first emission area EA1 and the second emission area EA2 such that they overlap each other in the third direction DR3.

The second color filter CF2 and the third color filter CF3 may be located in the non-emission area NEA between the second emission area EA2 and the third emission area EA3 such that they overlap each other in the third direction.

As another example, as shown in FIG. 9, the first color filter CF1, the second color filter CF2, and the third color filter CF3 may be located in the non-emission area NEA between the first emission area EA1 and the second emission area EA2, and in the non-emission area NEA between the second emission area EA2 and the third emission area EA3, such that they overlap each other in the third direction DR3.

As the overlapping color filters work as the black matrix, it is possible to reduce or prevent mixing of lights emitted from the light-emitting elements LE in the adjacent emission areas EA1, EA2, and EA3.

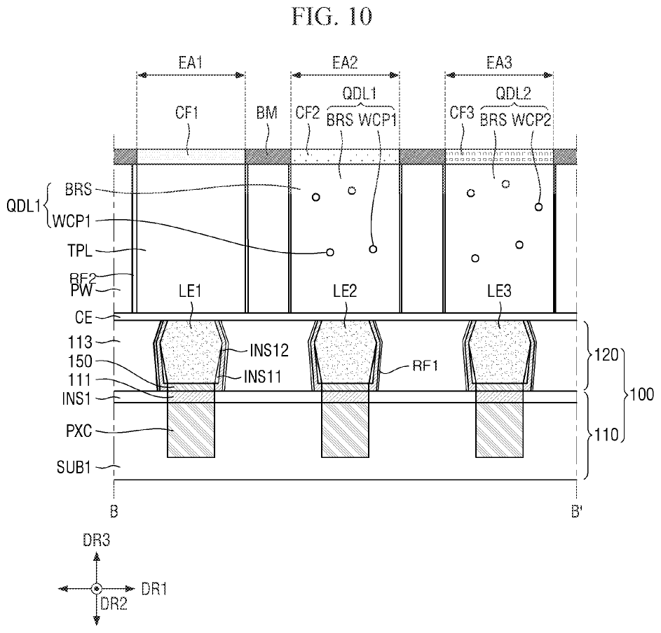

FIG. 10 is a cross-sectional view showing yet another example of the display panel taken along the line B-B′ of FIG. 3. The one or more embodiments corresponding to FIG. 10 are different from the one or more embodiments corresponding to FIG. 5 in that a first light-emitting element LE1, a second light-emitting element LE2, and a third light-emitting element LE3 are light-emitting elements emitting the first light, and that a transparent layer TPL is located in each of first emission areas EA1, that a first wavelength conversion layer QDL1 is located in each of second emission areas EA2, and that a second wavelength conversion layer QDL2 is located in each of third emission areas EA3. To avoid redundancy, the elements of FIG. 10 identical to those of FIG. 5 will not be described again.

The first light-emitting element LE1, the second light-emitting element LE2, and the third light-emitting element LE3 emit first light. For example, the first light may have a central wavelength range of about 450 nm to about 495 nm (e.g., may be light in the blue wavelength range).

The transparent layer TPL may be located on the common electrode CE in each of the first emission areas EA1. The transparent layer TPL may overlap with the light-emitting element LE in the third direction DR3 in each of the first emission areas EA1. The transparent layer TPL may completely cover the light-emitting element LE in each of the first emission areas EA1.

The transparent layer TPL may include a light-transmitting organic material. For example, the transparent layer TPL may include an epoxy resin, an acrylic resin, a cardo resin, or an imide resin.

The first wavelength conversion layer QDL1 may be located on the common electrode CE in each of the second emission areas EA2. The first wavelength conversion layer QDL1 may overlap the second light-emitting element LE2 in the third direction DR3 in each of the second emission areas EA2. The first wavelength conversion layer QDL1 may completely cover the second light-emitting element LE2 in each of the second emission areas EA2.

The first wavelength conversion layer QDL1 may include a base resin BRS and first wavelength converting particles WCP1. The base resin BRS may include an epoxy resin, an acrylic resin, a cardo resin, an imide resin, etc. The first wavelength converting particles WCP1 may convert the first light emitted from the second light-emitting element LE into the second light. For example, the first wavelength converting particles WCP1 may convert light in the blue wavelength range into light in the green wavelength range.

The second wavelength conversion layer QDL2 may be located on the common electrode CE in each of the third emission areas EA3. The second wavelength conversion layer QDL2 may overlap the third light-emitting element LE3 in the third direction DR3 in each of the third emission areas EA3. The second wavelength conversion layer QDL2 may completely cover the third light-emitting element LE3 in each of the third emission areas EA3.

The second wavelength conversion layer QDL2 may include a base resin BRS and second wavelength converting particles WCP2. The base resin BRS may include an epoxy resin, an acrylic resin, a cardo resin, an imide resin, etc. The second wavelength converting particles WCP2 may convert the first light emitted from the third light-emitting element LE3 into the third light. For example, the third wavelength converting particles WCP3 may convert light in the blue wavelength range into light in the red wavelength range.

In the second emission area EA2, some of the first lights emitted from the second light-emitting element LE2 are converted into the second light by the first wavelength converting particles WCP1 of the first wavelength conversion layer QDL1, such that the second light may pass through the second color filter CF2. In the second emission area EA2, the first lights that are emitted from the light-emitting elements LE, and that are not converted by the first wavelength conversion layer QDL1, may be absorbed or blocked by the second color filter CF2. Therefore, the second emission area EA2 may output the second light.

In the third emission area EA3, some of the first lights emitted from the third light-emitting element LE3 are converted into the third light by the second wavelength conversion layer QDL2, such that the third light may pass through the third color filter CF3. In the third emission area EA3, the first lights that are emitted from the third light-emitting element LE3, and that are not converted by the second wavelength conversion layer QDL2, may be absorbed or blocked by the third color filter CF3. Therefore, the third emission area EA3 may output the third light.

The shape of the transparent layer TPL, the shape of the wavelength conversion layer QDL, the shape of the first color filter CF1, the shape of the second color filter CF2, and the shape of the third color filter CF3 may follow the shape of the light-emitting elements LE when viewed from the top. For example, when the light-emitting elements LE have a rectangular shape when viewed from the top, the transparent layer TPL, the wavelength conversion layer QDL, the first color filter CF1, the second color filter CF2, and the third color filter CF3 each may have a rectangular shape when viewed from the top. Alternatively, the light-emitting elements LE may have a polygonal shape other than a rectangular shape, a circular shape, an elliptical shape or an irregular shape. In this instance, the transparent layer TPL, the wavelength conversion layer QDL, the first color filter CF1, the second color filter CF2, and the third color filter CF3 each may have the polygonal shape other than the rectangular shape, the circular shape, the elliptical shape or the irregular shape.

Alternatively, the shape of the transparent layer TPL, the shape of the wavelength conversion layer QDL, the shape of the first color filter CF1, the shape of the second color filter CF2, and the shape of the third color filter CF3 may not follow the shape of the light-emitting elements LE when viewed from the top. In this instance, the shape of the transparent layer TPL, the shape of the wavelength conversion layer QDL, the shape of the first color filter CF1, the shape of the second color filter CF2, and the shape of the third color filter CF3 may be different from the shape of the light-emitting elements LE when viewed from the top. In addition, the shape of the transparent layer TPL and the shape of the wavelength conversion layer QDL when viewed from the top may be different from the shape of the first color filter CF1, the shape of the second color filter CF2, and the shape of the third color filter CF3.

The second reflective layer RF2 is located on side surfaces of the transparent layer TPL and the wavelength conversion layers QDL. The second reflective layer RF2 serves to reflect some of the lights that are emitted from the light-emitting element LE and that travel in directions other than the vertical direction. The second reflective layer RF2 may be made of the same material as the first reflective layer RF1. For example, the second reflective layer RF2 may include a metal material having high reflectivity, such as aluminum (Al). The thickness of the reflective layer RF may be about 0.1 μm.

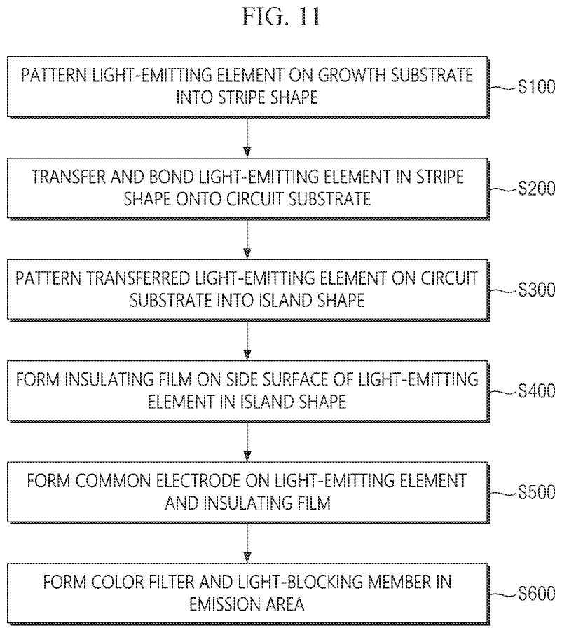

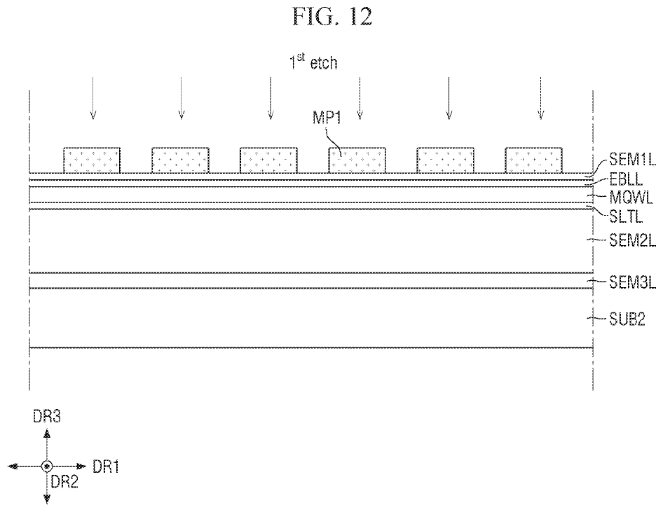

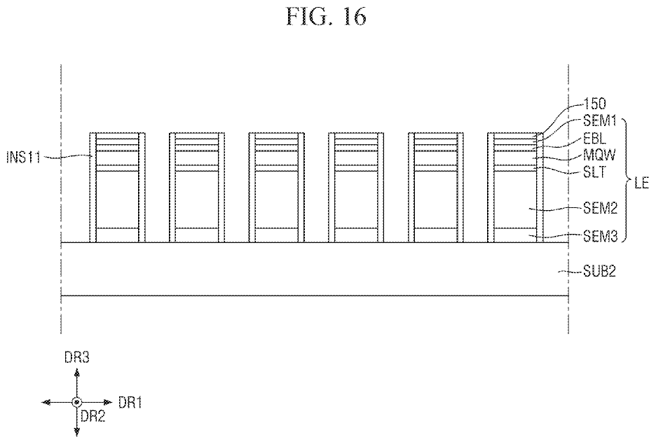

FIG. 11 is a flowchart for illustrating a method of fabricating a display device according to one or more embodiments of the present disclosure. FIGS. 12 to 28 are cross-sectional views, and FIGS. 29 and 30 are perspective views, for illustrating the method of fabricating a display device according to one or more embodiments of the present disclosure. FIGS. 12 to 30 show structures of layers of the display device 10 according to an order in which they may be formed. FIGS. 12 to 30 mainly show processes of fabricating and transferring light-emitting elements, which may be generally associated with the cross-sectional view of FIG. 5.

Referring to FIG. 11, a plurality of semiconductor material layers SEM3, SEM2L, SLTL, MQWL, EBLL, and SEM1L are formed on a growth substrate SUB2, and a plurality of light-emitting elements LE are patterned in a stripe shape (operation S100 in FIG. 11).

Initially, a growth substrate SUB2 is prepared. The growth substrate SUB2 may be a sapphire substrate (Al₂O₃) or a transparent silicon wafer including silicon. It should be understood, however, that the present disclosure is not limited thereto. According to one or more embodiments of the present disclosure, the growth substrate SUB2 is a sapphire substrate.

A plurality of semiconductor material layers SEM3L, SEM2L, SLTL, MQWL, EBLL, and SEM1L are formed on the growth substrate SUB2. The plurality of semiconductor material layers grown by the epitaxial method may be formed by growing a seed crystal. The method of forming the semiconductor material layers may include an electron beam deposition method, physical vapor deposition (PVD), chemical vapor deposition (CVD), plasma laser deposition (PLD), dual-type thermal evaporation, sputtering, metal-organic chemical vapor deposition (MOCVD), etc. For example, the method may be carried out by metal-organic chemical vapor deposition (MOCVD). It is, however, to be understood that the present disclosure is not limited thereto.

A precursor material for forming the plurality of semiconductor material layers is not particularly limited and any typical material well known in the art may be selected as long as it can form a target material. For example, the precursor material may be a metal precursor including an alkyl group, such as a methyl group or an ethyl group. For example, it may be, but is not limited to, a compound, such as trimethyl gallium (Ga(CH₃)₃), trimethyl aluminum (Al(CH₃)₃), or triethyl phosphate ((C₂H₅)₃PO₄).

For example, a third semiconductor material layer SEM3L is formed on the growth substrate SUB2. Although the third semiconductor layer SEM3 is a single layer in the drawings, the present disclosure is not limited thereto. The third semiconductor layer SEM3 may form a plurality of layers. The third semiconductor material layer SEM3L may reduce a lattice constant difference between the second semiconductor material layer SEM2L and the base substrate BSUB. For example, the third semiconductor material layer SEM3L may include an undoped semiconductor, and may be a material not doped into an n-type or p-type. In one or more embodiments, the third semiconductor material layer SEM3L may be, but is not limited to, at least one of undoped InAlGaN, GaN, AlGaN, InGaN, AlN, and/or InN.

The second semiconductor material layer SEM2L, the superlattice material layer SLTL, the active material layer MQWL, the electron blocking material layer EBLL, and the first semiconductor material layer SEM1L are sequentially formed on the third semiconductor material layer SEM3L using the above-described method.

Subsequently, the plurality of semiconductor material layers SEM3L, SEM2L, SLTL, MQWL, EBLL, and SEM1L are etched to form a plurality of light-emitting elements LE.

For example, a plurality of first mask patterns MP1 is formed on the first semiconductor material layer SEM1L. The first mask pattern MP1 may be a hard mask including an inorganic material or a photoresist mask including an organic material. The first mask pattern MP1 reduces or prevents the likelihood of the plurality of semiconductor material layers SEM3L, SEM2L, SLTL, MQWL, EBLL, and SEM1L being etched. Subsequently, parts of the plurality of semiconductor material layers are etched (1st etch) using the plurality of first mask patterns MP1 as a mask, to form a plurality of light-emitting elements LE in a stripe shape.

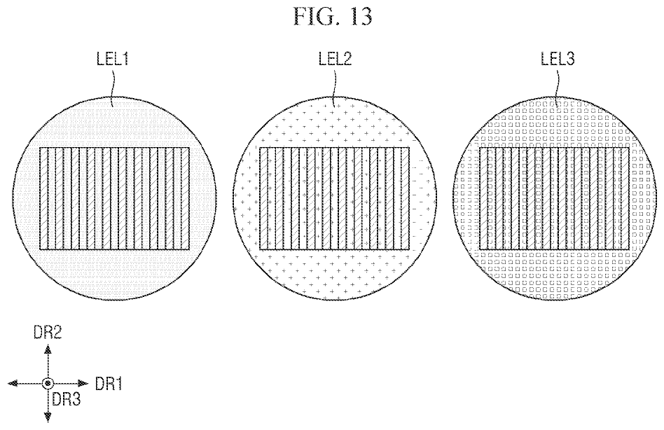

As shown in FIG. 13, light-emitting elements for emitting lights of different respective wavelengths may be formed on different growth substrates SUB2. For example, the first growth substrate LEL1 may form a first light-emitting element in a stripe shape that outputs first light, the second growth substrate LEL2 may form a second light-emitting element in a stripe shape that outputs second light, and the third growth substrate LEL3 may form a third light-emitting element in a stripe shape that outputs third light.

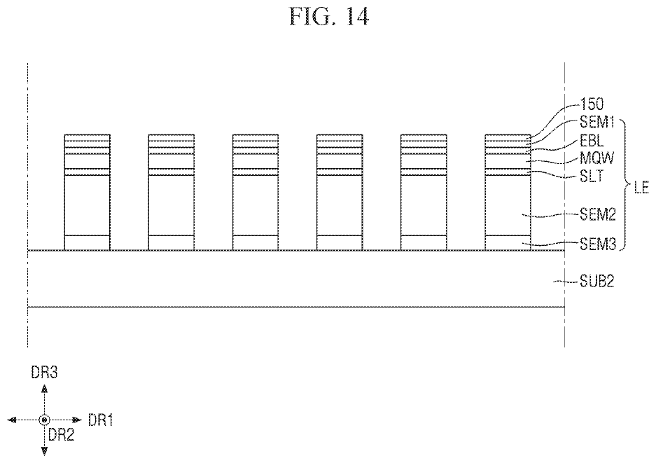

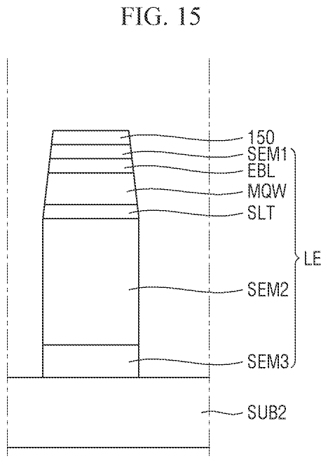

As shown in FIGS. 14 and 15, a plurality of semiconductor material layers SEM3L, SEM2L, SLTL, MQWL, EBLL, and SEM1L that do not overlap with the first mask pattern MP1 are etched and removed from the growth substrate SUB2. The other parts thereof, which overlap with the first mask pattern MP1 and thus are not etched, may be formed as a plurality of light-emitting elements LE.

The semiconductor material layers may be etched by typical methods well known in the art. For example, the process of etching the semiconductor material layers may include dry etching, wet etching, reactive ion etching (RIE), deep reactive ion etching (DRIE), inductively-coupled-plasma reactive ion etching (ICP-RIE), etc. The dry etching allows for anisotropic etching, and thus it may be suitable for vertical etching. When any of the above-described etching methods is used, the etching etchant may be Cl2 or O2. It is, however, to be understood that this is merely illustrative.

Parts of the plurality of semiconductor material layers SEM3L, SEM2L, SLTL, MQWL, EBLL, and SEM1L, which are in line with the first mask pattern MP1, are not etched and formed as a plurality of light-emitting elements LE. Therefore, the plurality of light-emitting elements LE includes the third semiconductor layer SEM3, the second semiconductor layer SEM2, the superlattice layer SLT, the active layer MQW, the electron-blocking layer EBL, and the first semiconductor layer SEM1.

The etching is carried out sequentially from the top layer to the bottom layer. Accordingly, the upper layers may be more etched than the lower layers. As the etching time increases, a difference between the widths of the upper layers and the widths of the lower layers may increase. As a result, the cross-section of the light-emitting elements LE may have a trapezoidal shape. For example, if the layers are etched in an island shape, it takes longer than etching them in the stripe shape as in one or more embodiments. Therefore, the upper layers may be etched more than the lower layers are etched. Subsequently, connection electrode material layers are stacked on the growth substrate SUB2, and are etched to form connection electrodes 150 on the light-emitting elements LE. The connection electrodes 150 may be formed directly on the upper surface of the first semiconductor layer SEM1 of the light-emitting elements LE.

As shown in FIG. 15, the width of the first semiconductor SEM1 may be less than the width of the active layer MQW located below the first semiconductor SEM1.

Subsequently, a first insulating layer INS11 surrounding the side surfaces of the light-emitting elements LE may be formed.

Subsequently, the light-emitting elements LE in a stripe shape formed by epitaxial growth on each growth substrate SUB2 may be transferred onto the semiconductor circuit substrate 110 including pixel electrode layers PXC via a temporary substrate and a relay substrate (operation S200 of FIG. 11).

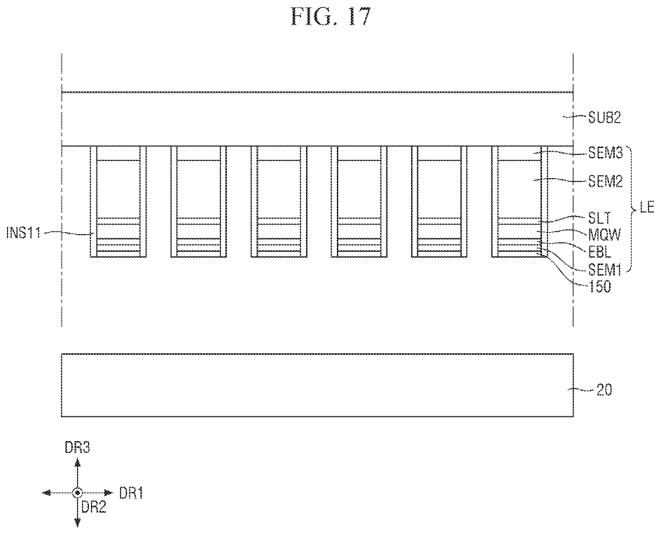

For example, referring to FIG. 17, the growth substrate SUB2 may be oriented such that the light-emitting elements LE in the stripe shape face a temporary substrate 20, and then may be brought into contact with the temporary substrate 20. Subsequently, the light-emitting elements are separated from the growth substrate SUB2 via a laser lift-off (LLO) process, and are attached to the temporary substrate 20. The laser lift-off process uses a laser, and a KrF excimer laser (wavelength of about 248 nm) may be used as the source.

The first light-emitting element grown on the first growth substrate LEL1, the second light-emitting element grown on the second growth substrate LEL2, and the third light-emitting element grown on the third growth substrate LEL3 are sequentially transferred to the temporary substrate 20. The temporary substrate 20 may be a transparent substrate made of sapphire, silicon, or transparent glass so that it is expandable and can be used in the LLO transfer process. The temporary substrate 20 may be formed to be larger than the growth substrate SUB2. Accordingly, not only a plurality of light-emitting elements LE located on one growth substrate SUB2 but also a plurality of light-emitting elements LE located on a plurality of growth substrates SUB2 can be transferred to a single temporary substrate 20 by the LLO process.

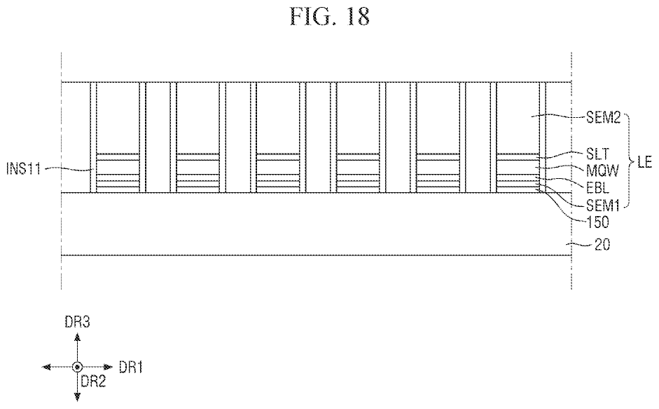

Referring to FIG. 18, the light-emitting elements LE are transferred onto the temporary substrate 20 such that the first semiconductor layer SEM1 is located on the lower side while the second semiconductor layer SEM2 is located on the upper side. For example, the cross section of the light-emitting elements LE transferred onto the temporary substrate 20 is an inverted trapezoidal shape, and they have a stripe shape when viewed from the top.

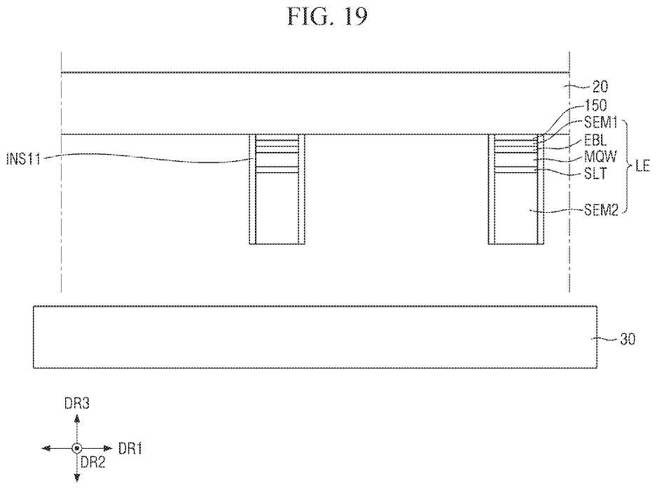

Subsequently, referring to FIG. 19, the light-emitting elements LE on the temporary substrate 20 are oriented such that they face a relay substrate 30. As shown in FIG. 19, the temporary substrate 20 may be expanded as needed.

The relay substrate 30 may be roughly the same size as, or larger than, the temporary substrate 20. Accordingly, all the light-emitting elements LE transferred from the plurality of growth substrates LEL1, LEL2, and LEL3 to the temporary substrate 20 may be concurrently or substantially simultaneously transferred.

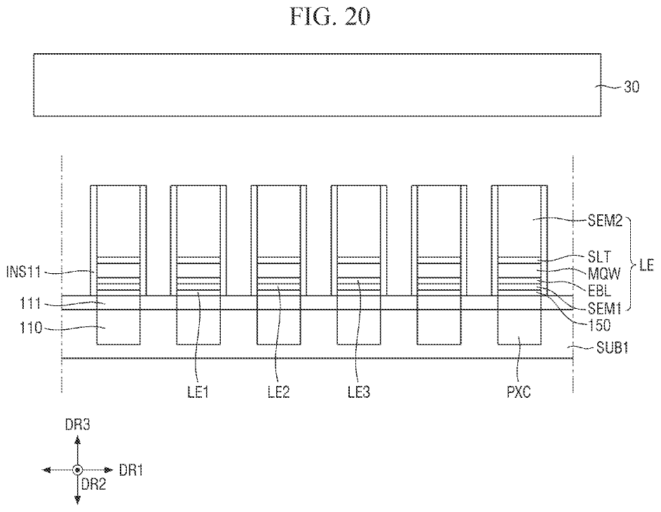

An adhesive layer may be applied to the relay substrate 30. The adhesive layer may be referred to as a dynamic release layer (DRL), and may be made of a PI (polyimide) material so that the relay substrate 30 can be easily separated from the first substrate SUB1 (see FIG. 20), which is a target substrate, during the LLO transfer process.

The relay substrate 30 may be a transparent substrate made of sapphire, silicon, or transparent glass so that it can be used in the LLO transfer process.

The light-emitting elements LE transferred to the relay substrate 30 are oriented such that the second semiconductor layer SEM2 is located on the lower side and the first semiconductor layer SEM1 is located on the upper side, like the stack structure of the light-emitting elements LE formed on the growth substrate SUB2. For example, the cross section of the light-emitting elements LE transferred onto the temporary substrate 20 is a trapezoidal shape, and they have a stripe shape when viewed from the top.

According to one or more embodiments of the present disclosure, the relay substrate 30 may have a circuit including lines for supplying current to the plurality of light-emitting elements LE transferred onto the relay substrate 30. Accordingly, it is possible to check whether the plurality of light-emitting elements LE transferred onto the relay substrate 30 operates normally, and to check whether there is defective one. In this manner, a defective light-emitting element may be removed, and a new light-emitting element may be located where it has been removed. That is to say, there is an opportunity to correct the light-emitting elements before they are transferred and bonded onto the target substrate.

Referring to FIG. 19, a plurality of light-emitting elements LE transferred from the temporary substrate 20 to the relay substrate 30 are attached to an adhesive layer formed on the relay substrate 30.

When a laser beam is irradiated onto the temporary substrate 20, the temporary substrate 20 is separated from the plurality of light-emitting elements LE by the laser beam so that they are transferred onto the relay substrate 30.

Referring to FIG. 20, the plurality of light-emitting elements LE transferred onto the relay substrate 30 may be transferred to the first substrate SUB1 by a LLO process.

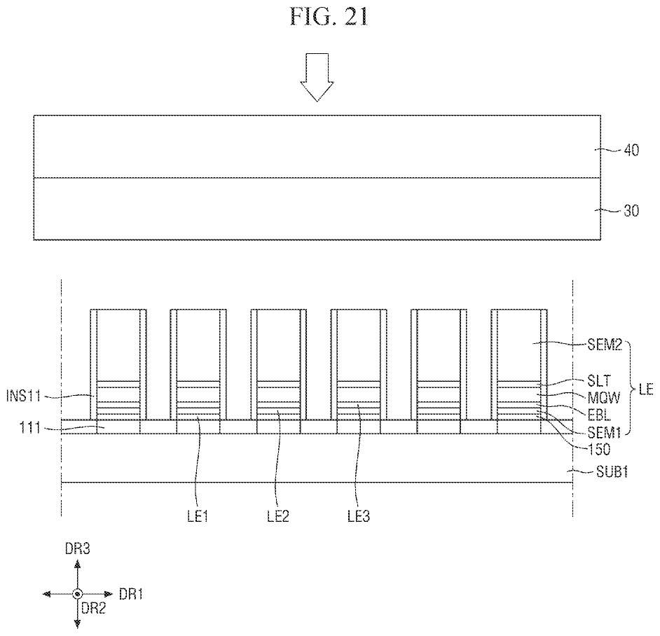

Referring to FIG. 21, a laser-transmitting member 40 may be located on the relay substrate 30.

The laser-transmitting member 40 may be made of a material that transmits a laser. The laser-transmitting member 40 may be made of any beam-transmitting material.

The laser-transmitting member 40 may be made of, for example, one of quartz, sapphire, fused silica glass, and/or diamond. The physical properties of the laser-transmitting member 40 made of quartz are different from the physical properties of the laser-transmitting member 40 made of sapphire. For example, when a laser at about 980 nm is irradiated, the transmittance of the laser-transmitting member 40 made of quartz may be about 85% to about 99%, and the transmittance of the laser-transmitting member 40 made of sapphire may be about 80% to about 90%. To reduce or prevent damage to the laser-transmitting member 40 made of quartz, and to improve the durability, a thin-film coating layer may be formed on the bottom surface of the laser-transmitting member 40 made of quartz. The thin-film coating layer formed on the bottom surface of the laser-transmitting member 40 may be formed by dielectric coating, SiC coating, or metallic material coating, which is typical optical coating.

A pressing member may be connected to the laser-transmitting member 40. The pressing member may press in one direction. For example, the pressing member may apply pressure in the third direction DR3. Accordingly, the laser-transmitting member 40 connected to the pressing member may press the relay substrate 30 in the third direction DR3.

As the laser is irradiated onto the connection electrode 150 while the relay substrate 30 is pressed with the laser-transmitting member 40, the laser LS can pass through the laser-transmitting member 40 and through the relay substrate 30 to be irradiated onto the connection electrode 150. Accordingly, the laser LS can apply heat to the connection electrode 150 up to the melting temperature of the connection electrode 150, to thereby bond the first substrate SUB1 to the connection electrode 150 by pressing and melting. Herein, the bonding by pressing and melting refers to that the connection electrode 150 is heated and melted by the irradiation of the laser LS, the light-emitting element LE and the pixel electrode 111 are melted and mixed, and then cooled and solidified after the laser supply is terminated. Because the light-emitting element LE and the pixel electrode 111 maintain conductivity even though they are cooled and solidified as they are melted and mixed, the pixel electrode 111 and the light-emitting element LE may be electrically and physically connected with each other.

As shown in FIG. 21, the light-emitting elements LE transferred onto the first substrate SUB1 are oriented such that the first semiconductor layer SEM1, the active layer MQW, and the second semiconductor layer SEM2 are arranged in order in a direction away from the first substrate SUB1.

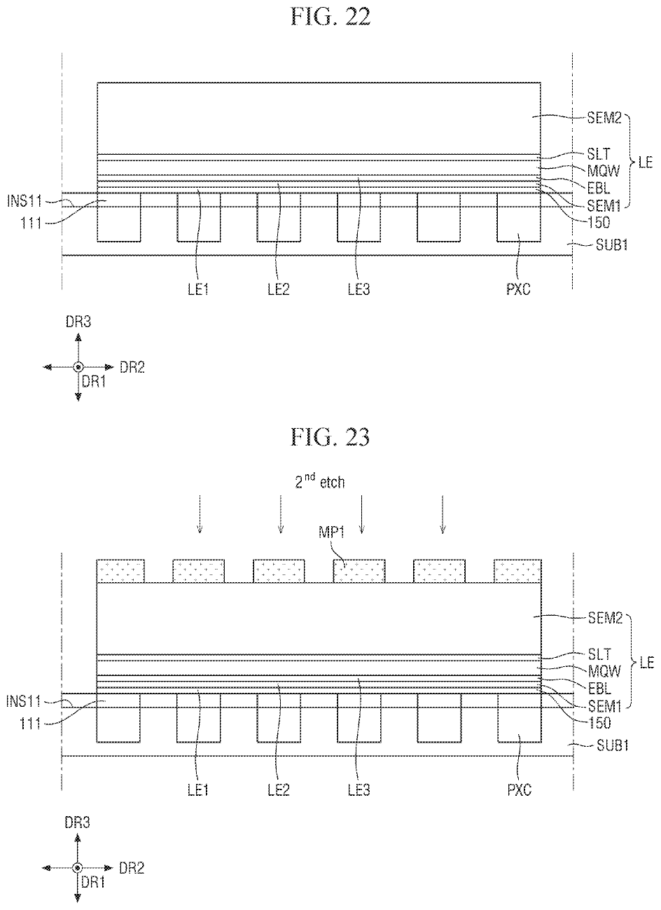

FIG. 21 is a cross-sectional view showing a first side of the first substrate SUB1. FIG. 22 is a cross-sectional view showing a second side of the first substrate SUB1. Referring to FIGS. 21 and 22, it can be seen that the light-emitting elements LE have a long stripe shape in the second direction DR2 on the second side.

Subsequently, the light-emitting elements transferred in the stripe shape are patterned into an island shape on the first substrate SUB1 (operation S300 of FIG. 11).

Referring to FIG. 23, a mask pattern MP1 may be located where the light-emitting elements LE in the island shape are to be formed. Accordingly, the mask pattern MP1 may overlap with the pixel electrode 111 in the third direction DR3. The mask pattern MP1 may include a conductive material, such as nickel (Ni). The thickness of the mask pattern MP1 may be about 0.01 μm to about 1 μm.

For example, the mask pattern MP1 might not be etched by an etchant for etching the light-emitting elements LE. Accordingly, the light-emitting element LE under the mask pattern MP1 may not be etched. Once the light-emitting element LE in the island shape is formed, the mask pattern MP1 is removed. As described above with reference to FIG. 14, the etching is sequentially carried out from the upper layers to the lower layers. Accordingly, the upper layers may be more etched than the lower layers. As a result, the uppermost layer of the second semiconductor layer SEM2, which is the top layer of the light-emitting element LE, is etched most rapidly, so that the uppermost layer of the second semiconductor layer SEM1 becomes narrower than the width of the middle layer thereof. Accordingly, the cross-section of the light-emitting element LE may have a hexagonal shape.

Referring to FIG. 24, a second insulating layer INS12 is formed on a side surface of the light-emitting element LE in the island space (operation S400 of FIG. 11). The second insulating layer INS12 may be implemented as, but is not limited to, an inorganic film, such as a silicon oxide film (SiO₂), an aluminum oxide film (Al₂O₃), and/or a hafnium oxide film (HfOx).

Accordingly, a first side surface of the light-emitting element LE includes both a first insulating layer INS11 and a second insulating layer INS12, and a second side surface includes the second insulating layer INS12. Therefore, the thickness of the insulating layer on the first side surface is different from the thickness of the insulating layer on the second side. The thickness of the insulating layer on the first side surface of the light-emitting element LE may be larger than the thickness of the insulating layer on the second side surface.

Subsequently, a common electrode CE is formed on the light-emitting element LE and the insulating layers INS11 and INS12 (operation S500 of FIG. 11).

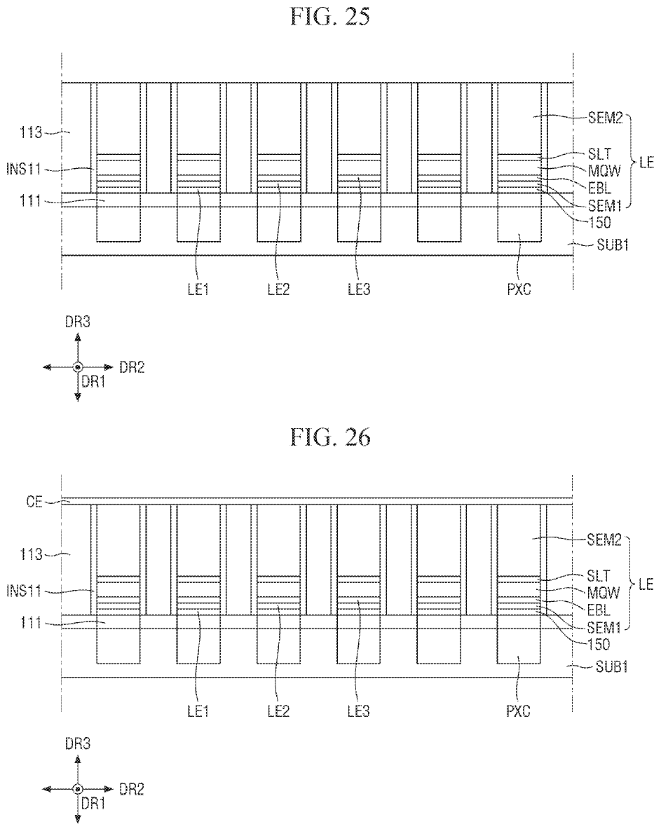

As shown in FIG. 25, a planarization layer 113 may be formed before the common electrode CE is formed. The planarization layer 113 may be formed of an organic layer, such as an acryl resin, an epoxy resin, a phenolic resin, a polyamide resin and a polyimide resin.

Subsequently, as shown in FIG. 26, the common electrode CE is deposited on the upper surface of the light-emitting element LE and the second insulating layer INS2. The common electrode CE may include a transparent conductive oxide (TCO), such as indium tin oxide (ITO), and/or indium zinc oxide (IZO).

Subsequently, color filters and a light-blocking member are formed in the emission area (operation S600 of FIG. 11).

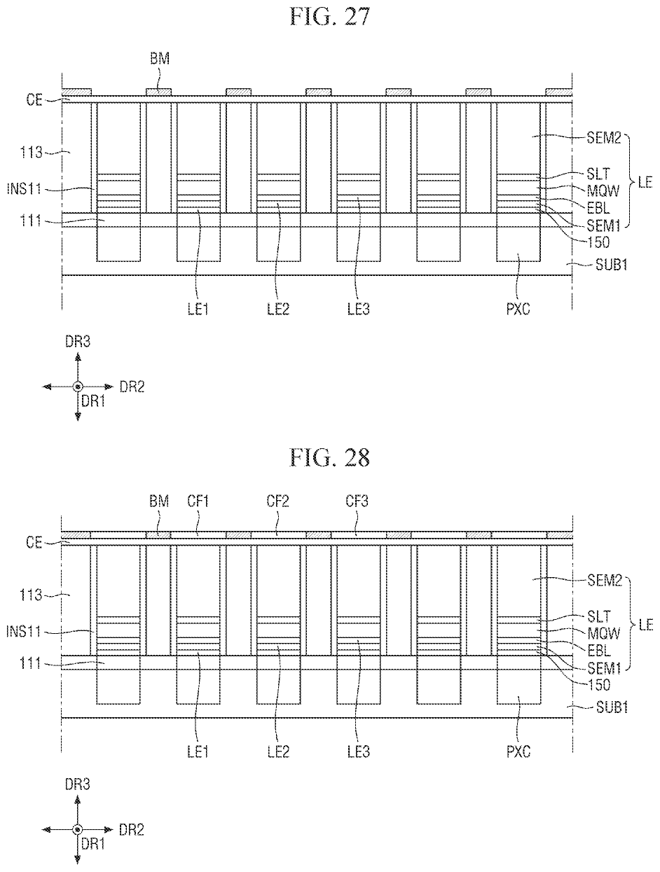

Referring to FIG. 27, a light-blocking member BM is formed in the non-emission area where no light-emitting element LE is located.

The light-blocking member BM is formed by applying and patterning a light-blocking material. The light-blocking member BM thus formed overlaps with the non-emission area, but does not overlap with the emission areas.

The light-blocking member BM may include an organic light-blocking material, and may be formed via processes of coating and exposing the organic light-blocking material to light. The light-blocking member BM may include a dye or pigment having light-blocking properties, and may be a black matrix.

When the light-blocking member BM is located on the common electrode CE, at least a part of external light is absorbed by the light-blocking member BM. By doing so, it is possible to reduce color distortion due to the reflection of the external light. In addition, the light-blocking member BM can reduce or prevent the color mixture occurring when light leaks between adjacent emission areas, thereby further improving the color gamut.

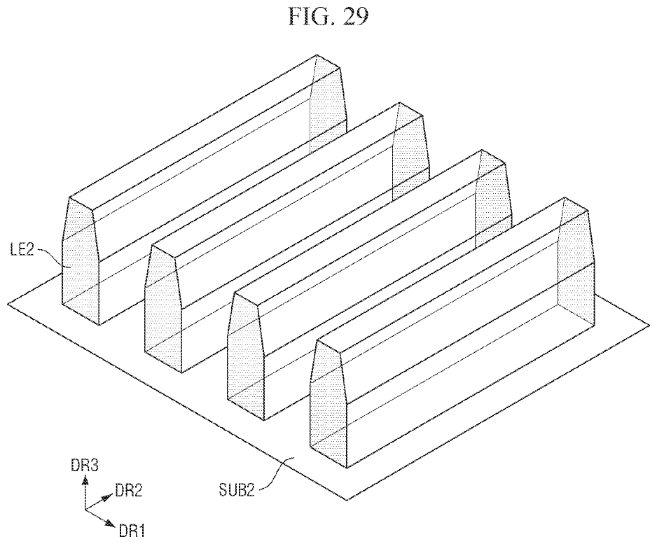

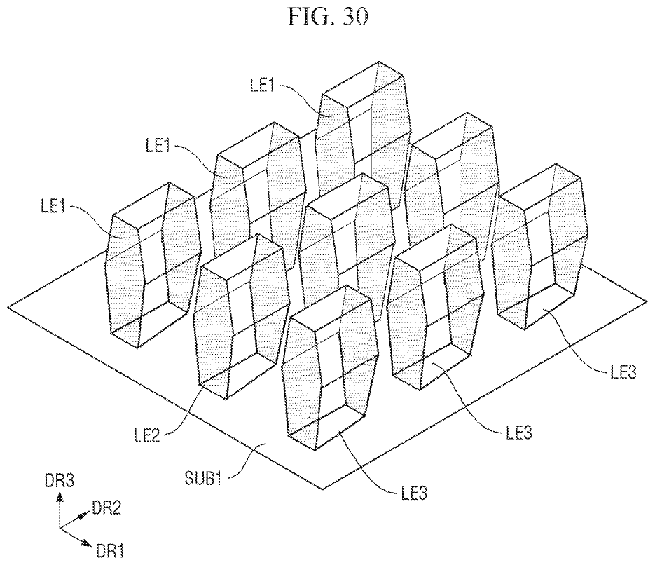

Subsequently, referring to FIG. 28, color filters CF1, CF2, and CF3 are formed on the common electrode CE partitioned by the light-blocking member BM. The color filters CF1, CF2, and CF3 may be formed via a photo process. The color filters CF1, CF2, and CF3 may have, but is not limited to, a thickness of about 1 μm or less.

FIG. 29 is a perspective view showing light-emitting elements LE2 that are first patterned in a stripe shape on a growth substrate SUB2 according to one or more embodiments. FIG. 30 is a perspective view showing first light-emitting elements LE1, second light-emitting elements LE2, and third light-emitting elements LE3 that are second patterned in an island shape on a first substrate SUB1.

As can be seen from FIGS. 29 and 30, the light-emitting elements LE2 are first patterned in a stripe shape on the growth substrate SUB2, and then are transferred to the first substrate SUB1 such that they are inverted/upside down. Subsequently, the secondary patterning into the island shape is carried out, so that etching damage can be dispersed across the upper portion and the lower portion. Accordingly, it is possible to reduce damage to the active layer located in the intermediate layer of the light-emitting elements LE1, LE2, and LE3, and thus light-emitting efficiency can be improved.

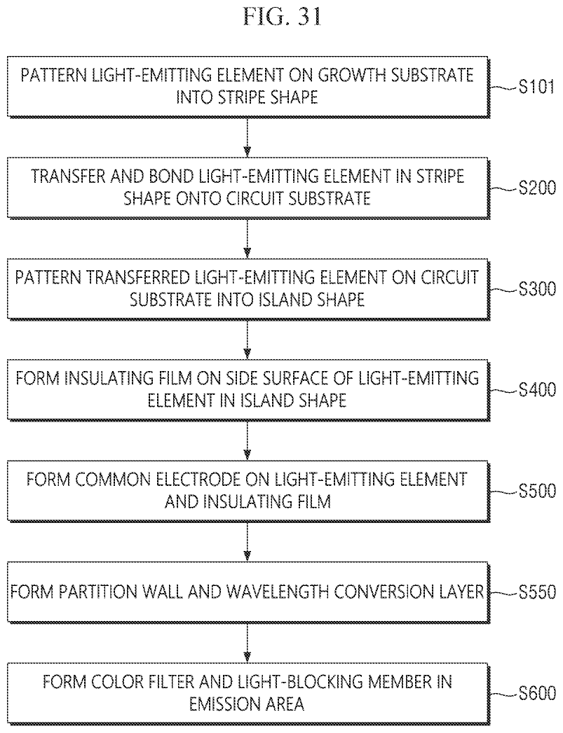

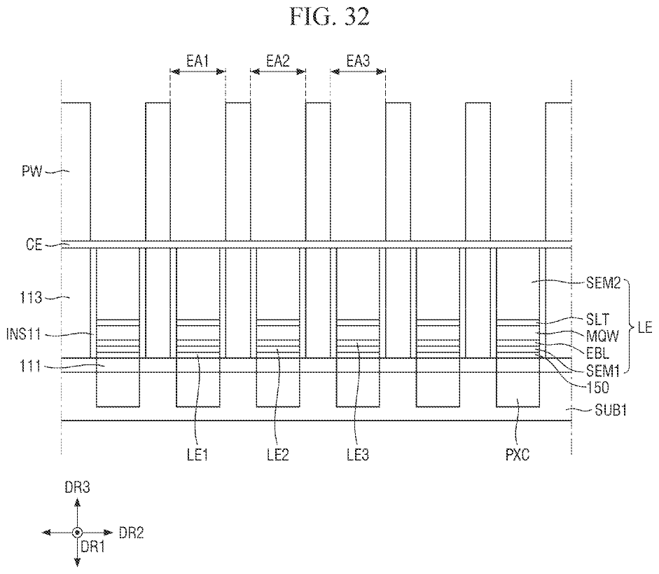

FIG. 31 is a flowchart for illustrating a method of fabricating a display device according to one or more other embodiments of the present disclosure. FIGS. 32 to 34 are cross-sectional views for illustrating the method of fabricating a display device according to one or more embodiments of the present disclosure. FIGS. 32 to 34 mainly show differences from the method of FIGS. 11 to 30, which may be generally associated with the cross-sectional view of FIG. 10.

The biggest difference between FIG. 31 and FIG. 11 is that a plurality of light-emitting elements emits a first light, and thus a wavelength conversion layer outputs the first light, a second light, and a third light from a first emission area, a second emission area, and a third emission area, respectively.

Referring to FIG. 31, a plurality of semiconductor material layers SEM3, SEM2L, SLTL, MQWL, EBLL, and SEM1L is formed on the growth substrate SUB2 and a plurality of light-emitting elements LE is patterned in a stripe shape (operation S101 in FIG. 31).

A first insulating layer INS11 surrounding the side surface of the light-emitting elements LE may be formed.

Subsequently, the light-emitting elements LE in the stripe shape formed by epitaxial growth on each growth substrate SUB2 may be transferred onto the semiconductor circuit substrate 110 including pixel circuits PXC via a temporary substrate and a relay substrate (operation S200 of FIG. 31).

Subsequently, the light-emitting elements transferred in the stripe shape are patterned into an island shape on the first substrate SUB1 (operation S300 of FIG. 31).

A second insulating layer INS12 is formed on the side surface of the light-emitting element LE in the island space (operation S400 of FIG. 31).

Subsequently, a common electrode CE is formed on the light-emitting element LE and the insulating layers INS11 and INS12 (operation S500 of FIG. 31).

Steps S200 to S500 of FIG. 31 may be respectively similar or identical to operations S200 to S500 of FIG. 11. Therefore, redundant descriptions thereof will be omitted.

Subsequently, a partition wall and a wavelength conversion layer are formed on the common electrode CE (operation S550 of FIG. 31).

For example, an organic insulating material is applied on the common electrode CE as shown in FIG. 32. Subsequently, a mask pattern is located in the non-emission area to perform patterning. Accordingly, the non-emission area is not etched, and thus a partition wall PW is formed, and a space for the wavelength conversion layer QDL may be formed in the emission area where the mask pattern is not located. The upper portion of the common electrode CE is exposed at the bottom of the space for the wavelength conversion layer QDL. Subsequently, the mask pattern is removed.

Subsequently, a reflective layer RF2 may be deposited on the partition wall PW and on the sidewall where the space for the wavelength conversion layer is formed. As in the forming the reflective layer RF2, a large voltage difference is formed in the third direction DR3 without any mask, and the reflective layer is etched using an etchant. Therefore, the reflective layer RF located on the partition wall PART and on the upper surface of the light-emitting elements LE can be removed in each of the first emission areas EA1, the second emission areas EA2, and the third emission areas EA3. The reflective layer RF located on the side surfaces of the partition wall PW may not be removed. Therefore, the reflective layer RF may be located on the side surfaces of the partition wall PW in each of the first emission areas EA1, the second emission areas EA2, and the third emission areas EA3.

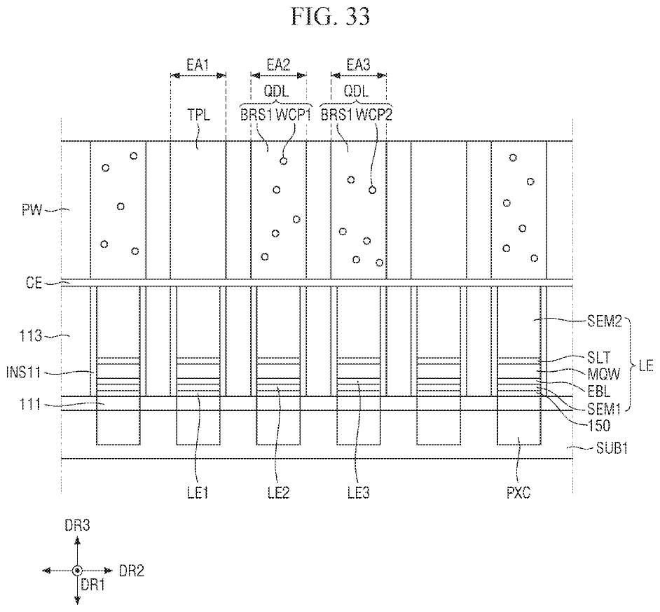

Subsequently, as shown in FIG. 33, a wavelength conversion layer QDL is formed in the space for the wavelength conversion layer QDL between the partition walls PW. A plurality of spaces for the wavelength conversion layer QDL may be filled with the wavelength conversion layer QDL. A transparent layer TPL is formed in the space between the partition walls PW of the first emission area EA1, and a first wavelength conversion layer QDL is formed in a space between the partition walls PW of the second emission area EA2. The first wavelength conversion layer QDL may be formed by a solution process, such as inkjet printing and imprinting with a solution in which the first wavelength converting particles WCP1 are mixed in a first base resin BRS1, but the present disclosure is not limited thereto. In this manner, a second wavelength conversion layer QDL is formed in a space between the partition walls PW of the third emission area EA3. The second wavelength conversion layer QDL may be formed by a solution process, such as inkjet printing and imprinting with a solution in which second wavelength converting particles WCP2 are mixed in a second base resin BRS2.

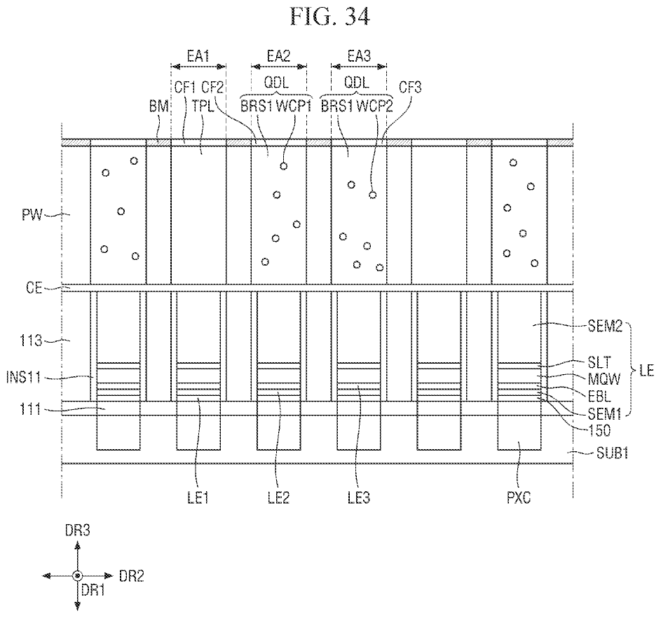

Subsequently, as shown in FIG. 34, a light-blocking member BM and a plurality of color filters CF1, CF2, and CF3 are formed (operation S600 of FIG. 31).

The light-blocking member BM is formed by applying and patterning a light-blocking material. The light-blocking member BM thus formed overlaps with the non-emission area but does not overlap with the emission areas.

Color filters CF1, CF2, and CF3 are formed on the common electrode CE partitioned by the light-blocking member BM. The color filters CF1, CF2, and CF3 may be formed via a photo process. The color filters CF1, CF2, and CF3 may have, but are not limited to, a thickness of about 1 μm or less.

However, the aspects of the disclosure are not restricted to the one set forth herein. The above and other aspects of the disclosure will become more apparent to one of daily skill in the art to which the disclosure pertains by referencing the claims, with functional equivalents thereof to be included therein.

What is claimed is:

1. A display device comprising:
a substrate;
pixel electrodes above the substrate;
light-emitting elements above the pixel electrodes, extending in a thickness direction of the substrate, and having a polyhedral shape in the thickness direction, a width of a middle portion of the polyhedral shape being greater than a width of an upper portion of the polyhedral shape and greater than a width of a lower portion of the polyhedral shape; and
a common electrode above the light-emitting elements.

2. The display device of claim 1, wherein the light-emitting elements comprise a first semiconductor layer above the pixel electrodes, an active layer above the first semiconductor layer, and a second semiconductor layer above the active layer.

3. The display device of claim 2, wherein a width of the active layer is greater than a width of the first semiconductor layer, and is greater than a width of a top of the second semiconductor layer.

4. The display device of claim 1, wherein a cross section of the polyhedral shape is a hexagon.

5. The display device of claim 1, wherein the light-emitting elements comprise a first insulating layer on a first side surface, and a second insulating layer on the first insulating layer and on a second side surface adjacent to the first side surface.

6. The display device of claim 1, wherein the light-emitting elements comprise respective insulating layers on a first side surface, and on a second side surface that is adjacent to the first side surface, and having different respective thicknesses.

7. The display device of claim 6, further comprising a reflective layer on an outer side of the insulating layers.

8. The display device of claim 1, further comprising a color filter above the common electrode overlapping the light-emitting elements.

9. The display device of claim 8, further comprising a light-blocking member above the common electrode, and between the light-emitting elements in plan view.

10. The display device of claim 9, wherein the light-emitting elements comprise a first light-emitting element for outputting a first light, a second light-emitting element for outputting a second light, and a third light-emitting element for outputting a third light.

11. The display device of claim 9, further comprising a wavelength conversion layer between the light-emitting elements and the color filter for converting a wavelength of light,
wherein the light-emitting elements are configured to output a first light.

12. The display device of claim 11, further comprising a reflective layer on a side surface of the wavelength conversion layer.

13. A method of fabricating a display device, the method comprising:
patterning light-emitting elements on a growth substrate and in a stripe shape in plan view;
forming a first insulating layer surrounding the light-emitting elements in plan view;
transferring the light-emitting elements onto a circuit substrate;
patterning the light-emitting elements to be in an island shape in plan view;
forming a second insulating layer surrounding side surfaces of the light-emitting elements in plan view; and
forming a common electrode above the light-emitting elements.

14. The method of claim 13, wherein the transferring the light-emitting elements onto the circuit substrate comprises:
transferring the light-emitting elements onto a temporary substrate;
transferring the light-emitting elements onto a relay substrate; and
transferring the light-emitting elements onto the circuit substrate.

15. The method of claim 14, wherein the light-emitting elements grown on the growth substrate comprise a first semiconductor layer, an active layer, and a second semiconductor layer sequentially stacked above the growth substrate, and
wherein the light-emitting elements transferred onto the circuit substrate comprise the first semiconductor layer, the active layer, and the second semiconductor layer sequentially stacked above the circuit substrate, and have a cross section of a polyhedral shape in a thickness direction, a width of a middle portion of the polyhedral shape being greater than a width of an upper portion of the polyhedral shape and greater a width of a lower portion of the polyhedral shape.

16. The method of claim 13, wherein the transferring the light-emitting elements onto the circuit substrate comprises bonding the light-emitting elements to the circuit substrate.

17. The method of claim 13, further comprising forming a reflective layer surrounding the second insulating layer in plan view.

18. The method of claim 13, further comprising growing a first light-emitting element for emitting a first light on a first growth substrate, a second light-emitting element for emitting a second light on a second growth substrate, and a third light-emitting element for emitting a third light on a third growth substrate.

19. The method of claim 13, further comprising:
forming a space for a wavelength conversion layer and for a light-transmitting layer, and forming a partition wall, by applying an organic insulating material layer above the common electrode, and by etching the organic insulating material layer above the light-emitting elements; and
forming the wavelength conversion layer and the light-transmitting layer above the space.

20. The method of claim 19, wherein the light-emitting elements are configured to emit a first light,
wherein the light-transmitting layer is configured to transmit the first light, and
wherein the wavelength conversion layer comprises a first wavelength conversion layer that converts a first wavelength of the first light into a second wavelength of a second light, and a second wavelength conversion layer that converts the first wavelength of the first light into a third wavelength of a third light.
